(19) United States
(12) Patent Application Publication
(10) Pub. No.: US 2020/0159121 A1
(43) Pub. Date: May 21, 2020

(54) METAL-CONTAINING FILM-FORMING COMPOSITION, METAL-CONTAINING FILM AND PATTERN-FORMING METHOD

(71) Applicant: JSR CORPORATION, Tokyo (JP)

(72) Inventors: Ryuichi SERIZAWA, Tokyo (JP); Nozomi SATOU, Tokyo (JP); Yuusuke OOTSUBO, Tokyo (JP)

(73) Assignee: JSR CORPORATION, Tokyo (JP)

(21) Appl. No.: 16/750,616

(22) Filed: Jan. 23, 2020

Related U.S. Application Data
(63) Continuation of application No. PCT/JP2018/027387, filed on Jul. 20, 2018.

(30) Foreign Application Priority Data
Jul. 24, 2017 (JP) 2017-143105

(51) Int. Cl. G03F 7/11; C09D 7/63

(52) U.S. Cl. CPC G03F 7/11; G03F 7/162; C09D 7/63

(57) ABSTRACT

A metal-containing film-forming composition for lithography with an extreme ultraviolet ray or electron beam includes a compound and a solvent. The compound includes a metal element and an oxygen atom, and further includes a metal-oxygen covalent bond. The metal element in the compound belongs to period 3 to period 7 of group 3 to group 15 in periodic table. The solvent includes a first solvent component having a normal boiling point of less than 160° C. and a second solvent component having a normal boiling point of no less than 160° C. and less than 400° C. The solvent includes an alcohol solvent. A percentage content of the alcohol solvent in the solvent is no less than 30% by mass.

### CROSS-REFERENCE TO RELATED APPLICATIONS

The present application is a continuation application of International Application No. PCT/JP2018/027387, filed Jul. 20, 2018, which claims priority to Japanese Patent Application No. 2017-143105, filed Jul. 24, 2017. The contents of these applications are incorporated herein by reference in their entirety.

### BACKGROUND OF THE INVENTION

### Field of the Invention

The present invention relates to a metal-containing film-forming composition for lithography with an extreme ultraviolet ray or electron beam, a metal-containing film for lithography with an extreme ultraviolet ray or electron beam, and a pattern-forming method.

### Discussion of the Background

In pattern formation of semiconductor elements and the like, resist processes are frequently employed in which a resist film laminated to a substrate via an underlayer film such as an organic or inorganic antireflective film is exposed and developed, and etching is carried out using a resultant resist pattern as a mask (see Japanese Unexamined Patent Application, Publication No. 2004-310019 and PCT International Publication No. 2012/039337). In recent years, highly enhanced integration of semiconductor devices has advanced further, and exposure light to be used tends to have a shorter wavelength, as from a KrF excimer laser beam (248 nm) or an ArF excimer laser beam (193 nm) to an extreme ultraviolet ray (13.5 nm; EUV) or an electron beam (EB).

### SUMMARY OF THE INVENTION

Miniaturization of resist patterns formed by exposure to EUV and development has advanced to a level of line widths of no greater than 20 nm Decreases in thicknesses of underlayer films for resists have also advanced to a level of the film thicknesses being no greater than 30 nm. Due to such advanced thinning of the underlayer films, process yields of semiconductor elements may be reduced since the size in resist patterns formed by EUV lithography processes may vary when the film thicknesses of the underlayer films to be formed are different for each of the substrates through, for example, varying time periods from applying the composition for forming so the underlayer film until heating the coating film for the substrate to be processed. Therefore, in the EUV lithography process, the composition for forming the underlayer film needs to enable formation of an underlayer film with a variation-inhibiting property regarding coating film thickness and a variation-inhibiting property regarding resist sensitivity, each being superior. It is supposed that also in an EB lithography process, the composition for forming the underlayer film needs to enable formation of an underlayer film with a variation-inhibiting property regarding coating film thickness and a variation-inhibiting property regarding resist sensitivity, each being superior.

According to an aspect of the present invention, a metal-containing film-forming composition for lithography with an extreme ultraviolet ray or electron beam includes a compound and a solvent. The compound includes a metal element and an oxygen atom, and further includes a metal-oxygen covalent bond. The metal element in the compound belongs to period 3 to period 7 of group 3 to group 15 in periodic table. The solvent includes a first solvent component having a normal boiling point of less than 160° C. and a second solvent component having a normal boiling point of no less than 160° C. and less than 400° C. The solvent includes an alcohol solvent. A percentage content of the alcohol solvent in the solvent is no less than 30% by mass.

According to another aspect of the present invention, a metal-containing film for lithography with an extreme ultraviolet ray or electron beam is formed from the metal-containing film-forming composition.

According to further aspect of the present invention, a pattern-forming method includes applying the metal-containing film-forming composition directly or indirectly so on at least an upper face side of a substrate to form a metal-containing film. A composition for resist film formation is directly or indirectly applied on an upper face side of the metal-containing film to form a resist film. The resist film is exposed to an extreme ultraviolet ray or electron beam. The resist film exposed is developed.

### DESCRIPTION OF THE EMBODIMENTS

According to one embodiment of the invention, a metal-containing film-forming composition for lithography with an extreme ultraviolet ray or electron beam comprises: a compound comprising a metal-oxygen covalent bond (hereinafter, may be also referred to as “(A) compound” or “compound (A)”); and a solvent (hereinafter, may be also referred to as “(B) solvent” or “solvent (B)”), wherein a metal element constituting the compound (A) belongs to period 3 to period 7 of group 3 to group 15 in periodic table, the solvent (B) comprises a first solvent component having a normal boiling point of less than 160° C. (hereinafter, may be also referred to as “(B1) solvent component” or “solvent component (B1)”) and a second solvent component having a normal boiling point of no less than 160° C. and less than 400° C. (hereinafter, may be also referred to as “(B2) solvent component” or “solvent component (B2)”), the solvent (B) comprises an alcohol solvent, and a percentage content of the alcohol solvent in the solvent (B) is no less than 30% by mass.

According to another embodiment of the present invention, a metal-containing film for lithography with an extreme ultraviolet ray or electron beam is formed from the metal-containing film-forming composition for lithography with an extreme ultraviolet ray or electron beam of the one embodiment of the present invention.

According to yet another embodiment of the present invention, a pattern-forming method comprises: applying the metal-containing film-forming composition of the one embodiment of the present invention directly or indirectly on at least an upper face side of a substrate to form a metal-containing film; applying a composition for resist film formation directly or indirectly on an upper face side of the metal-containing film to form a resist film; exposing the resist film to an extreme ultraviolet ray or electron beam; and developing the resist film exposed.

The “metal element” as referred herein to means an element a simple substance of which is a metal, and does not include elements falling under metalloid elements such as boron, silicon and arsenic.

According to the metal-containing film-forming composition for lithography with an extreme ultraviolet ray or electron beam, the metal-containing film and for lithography with an extreme ultraviolet ray or electron beam, and the pattern-forming method of the embodiments of the present invention, a metal-containing film with a variation-inhibiting property regarding coating film thickness and a variation-inhibiting property regarding resist sensitivity, each being superior, is formed, and by using this metal-containing film, resist pattern size produced by a lithography process with an extreme ultraviolet ray or electron beam becomes less likely to vary, thereby enabling a process yield of a semiconductor element to increase. Therefore, these can be suitably used for the manufacture, etc. of semiconductor devices, for which further progress of microfabrication is expected in the future.

Hereinafter, embodiments of the metal-containing film-forming composition for lithography with an extreme ultraviolet ray or electron beam (hereinafter, may be merely referred to as “film-forming composition”), the metal-containing film for lithography with an extreme ultraviolet ray or electron beam (hereinafter, may be merely referred to as “metal-containing film”) and the pattern-forming method of the embodiments of the present invention will be described in detail.

### Film-Forming Composition

The film-forming composition of one embodiment of the present invention contains the compound (A) and the solvent (B). The film-forming composition may also contain optional component(s) within a range not leading to impairment of the so effects of the present invention. Each component will be described below.

### (A) Compound

The compound (A) has a metal-oxygen covalent bond. It is preferred that the compound (A) is not an ionic compound such as a salt. Due to having the metal-oxygen covalent bond, the compound (A) is capable of changing a solubility in a developer solution through a structural change of the compound (A) and/or a change of the group bonding to the metal atom of the compound (A) upon an exposure, thereby enabling a pattern to be formed.

The metal element constituting the compound (A) (hereinafter, may be also referred to as “metal element (a)”) belongs to period 3 to period 7 of group 3 to group 15 in the periodic table.

Examples of the metal element (a) belonging to group 3 include scandium, yttrium, lanthanum, cerium, and the like;

examples of the metal element (a) belonging to group 4 include titanium, zirconium, hafnium, and the like;

examples of the metal element (a) belonging to group 5 include vanadium, niobium, tantalum, and the like;

examples of the metal element (a) belonging to group 6 include chromium, molybdenum, tungsten, and the like;

examples of the metal element (a) belonging to group 7 include manganese, rhenium, and the like;

examples of the metal element (a) belonging to group 8 include iron, ruthenium, osmium, and the like;

examples of the metal element (a) belonging to group 9 include cobalt, rhodium, iridium, and the like;

examples of the metal element (a) belonging to group 10 include nickel, palladium, platinum, and the like;

examples of the metal element (a) belonging to group 11 include copper, silver, gold, and the like;

examples of the metal element (a) belonging to group 12 include zinc, cadmium, mercury, and the like;

examples of the metal element (a) belonging to group 13 include aluminum, gallium, indium, and the like;

examples of the metal element (a) belonging to group 14 include germanium, tin, lead, and the like; and

examples of the metal element (a) belonging to group 15 include antimony, bismuth, and the like.

The metal element (a) constituting the compound (A) is preferably the metal element (a) belonging to period 3 to period 7 of group 3 to group 15, more preferably the metal element (a) belonging to period 3 to period 7 of group 4 to group 6 or group 13, and still more preferably titanium, zirconium, hafnium or aluminum.

The compound (A) may include an element (other element) other than the metal element (a) and oxygen. Examples of the other element include: metalloid elements such as boron and silicon; non-metal elements such as carbon, hydrogen, nitrogen, phosphorus, sulfur and halogen; and the like. Of these, silicon, carbon or hydrogen is preferred.

The lower limit of the percentage content of the atom of the metal element (a) in the compound (A) is preferably 10% by mass, more preferably 20% by mass, and still more preferably 30% by mass. The upper limit of the percentage content is preferably 50% by mass. The percentage content of the atom of the metal element (a) so may be determined by measurement in which a differential thermal balance (TG/DTA) is used. When the percentage content of the atom of the metal element (a) falls within the above range in the compound (A), the structural change of the compound (A) by an extreme ultraviolet ray or exposure to an electron beam can be more effectively promoted, and as a result, the variation-inhibiting property regarding coating film thickness and the variation-inhibiting property regarding resist sensitivity to an extreme ultraviolet ray or electron beam can be further improved.

The compound (A) is exemplified by a polynuclear complex having a bond of metal-oxygen-metal, and the like. The “polynuclear complex” as referred to herein means a complex having a plurality of metal atoms. By using such a compound (A) as the polynuclear complex, the variation-inhibiting property regarding coating film thickness and the variation-inhibiting property regarding resist sensitivity to an extreme ultraviolet ray or electron beam can be further improved. The polynuclear complex may also have a ligand. Such a polynuclear complex can be synthesized by, for example, hydrolytic condensation of a metal-containing compound having a hydrolyzable group, as described later.

In a case in which the compound (A) is the polynuclear complex, the lower limit of a polystyrene-equivalent weight average molecular weight (Mw) of the compound (A) as determined by gel permeation chromatography (GPC) is preferably 1,000, more preferably 1,500, and still more preferably 2,000. The upper limit of the Mw is preferably 10,000, more preferably 8,000, and still more preferably 6,000. When the Mw of the compound (A) falls within the above range, the variation-inhibiting property regarding coating film thickness and the variation-inhibiting property regarding resist sensitivity to an extreme ultraviolet ray or electron beam can be further improved.

Herein, the Mw of the compound (A) is a value determined by gel permeation chromatography (detector: differential refractometer) using GPC columns (Tosoh Corporation: “AWM-H”×2; “AW-H”×1; and “AW2500”×2) under an analytical condition involving a flow rate of 0.3 mL/min, an elution solvent of a mixture prepared by adding LiBr (30 mM) and citric acid (30 mM) to N,N′-dimethylacetamide, and a column temperature of 40° C., with mono-dispersed polystyrene as a standard.

The lower limit of the content of the compound (A) with respect to the total solid content of the film-forming composition is preferably 70% by mass, more preferably 80% by mass, and still more preferably 90% by mass. The upper limit of the content may be 100% by mass. When the content of the compound (A) falls within the above range, coating characteristics of the film-forming composition can be further improved. The “total solid content” of the film-forming composition as referred to herein means components other than the solvent (B). The film-forming composition may contain one, or two or more types of the compound (A).

Synthesis Method of Compound (A)

The compound (A) used may be a commercially available metal compound, or may be synthesized by, for example, a procedure of carrying out a hydrolytic condensation reaction by using a metal-containing compound having a hydrolyzable group (hereinafter, may be also referred to as “(b) metal-containing compound” or “metal-containing compound (b)”), or the like. In other words, the compound (A) may be derived from the metal-containing compound (b). The “hydrolytic condensation reaction” as referred to herein means a reaction in which a hydrolyzable group included in the metal-containing compound (b) is hydrolyzed to give —OH, and two —OHs thus obtained undergo dehydrative condensation to form —O—.

(b) Metal-Containing Compound

The metal-containing compound (b) may be: a metal compound (I) having a hydrolyzable group (hereinafter, may be also referred to as “metal compound (I)”); a hydrolysis product of the metal compound (I); a hydrolytic condensation product of the metal compound (I); or a combination thereof. The metal compound (I) may be used either alone of one type, or in a combination of two or more types thereof.

The hydrolyzable group is exemplified by a halogen atom, an alkoxy group, a carboxylate group, an acyloxy group, —NRR′, and the like, wherein R and R′ each independently represent a hydrogen atom or a monovalent organic group having 1 to 20 carbon atoms. The monovalent organic group having 1 to 20 carbon atoms which may be represented by R or R′ is exemplified by: a monovalent hydrocarbon group having 1 to 20 carbon atoms; a monovalent group (g) having a divalent hetero atom-containing group between two adjacent carbon atoms of the hydrocarbon group having 1 to 20 carbon atoms; a monovalent group obtained by substituting with a monovalent hetero atom-containing group a part or all of hydrogen atoms included in the hydrocarbon group or the group (g); and the like.

Examples of the halogen atom include a fluorine atom, a chlorine atom, a bromine atom, an iodine atom, and the like.

Examples of the alkoxy group include a methoxy group, an ethoxy group, a n-propoxy group, an i-propoxy group, a butoxy group, and the like.

Examples of the carboxylate group include an acetate group, a propionate group, a butyrate group, a n-hexanecarboxylate group, a n-octanecarboxylate group, and the like.

Examples of the acyloxy group include an acetoxy group, an ethylyloxy group, a propionyloxy group, a butyryloxy group, a t-butyryloxy group, a t-amylyloxy group, a n-hexanecarbonyloxy group, a n-octanecarbonyloxy group and the like.

Examples of the —NRR′ include an unsubstituted amino group, a methylamino group, a dimethylamino group, a diethylamino group, a dipropylamino group and the like.

As the hydrolyzable group, an alkoxy group is preferred, and an isopropoxy group or a butoxy group is more preferred.

In a case in which the metal-containing compound (b) is a hydrolytic condensation product of the metal compound (I), the hydrolytic condensation product of the metal compound (I) may be a hydrolytic condensation product of the metal compound (I) including the metal element (a) with a compound including a metalloid element, within a range not leading to impairment of the effects of the embodiments of the present invention. In other words, the hydrolytic condensation product of the metal compound (I) may also include a metalloid element within a range not leading to impairment of the effects of the embodiments of the present invention. Examples of the metalloid element include boron, silicon, arsenic, tellurium, and the like. The percentage content of the metalloid atom in the hydrolytic condensation product of the metal compound (I) with respect to the entirety of the atoms of the metal element (a) and the metalloid atoms in the hydrolytic condensation product is typically less than 50 atom %, preferably no greater than 30 atom %, and more preferably no greater than 10 atom %.

The metal compound (I) is exemplified by compounds represented by the following formula (1) (hereinafter, may be also referred to as a “metal compound (I-1)”), and the like. By using the metal compound (I-1), forming a stable compound (A) is enabled, thereby enabling the variation-inhibiting property regarding coating film thickness and the variation-inhibiting property regarding resist sensitivity to an extreme ultraviolet ray or electron beam to be further improved.

LₐMY_{b} (1)

In the above formula (1), M represents a metal atom; L represents a ligand; a is an integer of 0 to 6, wherein in a case in which a is no less than 2, a plurality of Ls are identical or different; Y represents a halogen atom, a hydrolyzable group selected from an alkoxy group, a carboxylate group, an acyloxy group or —NRR′, wherein R and R′ each independently represent a hydrogen atom or a monovalent organic group having 1 to 20 carbon atoms; and b is an integer of 2 to 6, wherein a plurality of Ys are identical or different, and L is a ligand not falling under the category of Y.

The metal atom represented by M is exemplified by atoms similar to those exemplified as the atom of the metal element (a) constituting the compound (A), and the like.

The ligand represented by L is exemplified by a monodentate ligand and a polydentate ligand.

Exemplary monodentate ligand includes a hydroxo ligand, a carboxy ligand, an amido ligand, an amine ligand, an ammonia ligand, an olefin ligand, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Examples of the amine ligand include a pyridine ligand, a trimethylamine ligand, a piperidine ligand, and the like.

Examples of the olefin ligand include linear olefins such as ethylene and propylene; cyclic olefins such as cyclopentene, cyclohexene and norbornene; and the like.

Exemplary polydentate ligand includes a ligand derived from a hydroxy acid ester, a ligand derived from a β-diketone, a ligand derived from a β-keto ester, a ligand derived from an α,α-dicarboxylic acid ester, a hydrocarbon having a π bond, diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the α,α-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having a π bond include:

chain dienes such as butadiene and isoprene;

cyclic dienes such as cyclopentadiene, methylcyclopentadiene, pentamethylcyclopentadiene, cyclohexadiene and norbornadiene;

aromatic hydrocarbons such as benzene, toluene, xylene, hexamethylbenzene, naphthalene and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

In the above formula (1), “a” is preferably 0 to 3, more preferably 0 to 2, still more preferably 1 or 2, and particularly preferably 2. When “a” is a value described above, stability of the compound (A) can be appropriately improved, and as a result, the variation-inhibiting property regarding coating film thickness and the variation-inhibiting property regarding resist sensitivity to an extreme ultraviolet ray or electron beam can be further improved.

The hydrolyzable group which may be represented by Y is exemplified by groups similar to those exemplified as the hydrolyzable group in the metal-containing compound (b), and the like.

In the above formula (1), b is preferably 2 to 4, more preferably 2 or 3, and still more preferably 2. When b is a value described above, the molecular weight of the compound (A), which is a hydrolytic condensation product, can be more appropriately increased, and as a result, the variation-inhibiting property regarding coating film thickness and the variation-inhibiting property regarding resist sensitivity to an extreme ultraviolet ray or electron beam can be further improved.

As the metal-containing compound (b), a metal alkoxide that is neither hydrolyzed nor hydrolytically condensed, and a metal alkoxide that has a ligand and is neither hydrolyzed nor hydrolytically condensed are preferred.

Examples of the metal-containing compound (b) include:

titanium-containing compounds such as diisopropoxybis(2,4-pentanedionato) titanium(IV), tetra-n-butoxy titanium(IV), tetra-n-propoxy titanium(IV), tri-n-butoxymonostearate titanium(IV), a titanium(IV) butoxide oligomer, aminopropyltrimethoxy titanium(IV), triethoxymono(2,4-pentanedionato) titanium(IV), tri-n-propoxymono(2,4-pentanedionato) titanium(IV), triisopropoxymono(2,4-pentanedionato) titanium and di-n-butoxybis(2,4-pentanedionato) titanium(IV);

zirconium-containing compounds such as dibutoxybis(ethylacetoacetate) zirconium(IV), di-n-butoxybis(2,4-pentanedionato) zirconium(IV), tetra-n-butoxy zirconium(IV), tetra-n-propoxy zirconium(IV), tetraisopropoxy zirconium(IV), aminopropyltriethoxy zirconium(IV), 2-(3,4-epoxycyclohexyl)ethyltrimethoxy zirconium(IV), γ-glycidoxypropyltrimethoxy zirconium(IV), 3-isocyanopropyltrimethoxy zirconium(IV), triethoxymono(2,4-pentanedionato) zirconium(IV), tri-n-propoxymono(2,4-pentanedionato) zirconium(IV), triisopropoxymono(2,4-pentanedionato) zirconium(IV), tri(3-methacryloxypropyl)methoxy zirconium(IV) and tri(3-acryloxypropyl)methoxy zirconium(IV);

hafnium-containing compounds such as diisopropoxybis(2,4-pentanedionato) hafnium(IV), tetrabutoxy hafnium(IV), tetraisopropoxy hafnium(IV), tetraethoxy hafnium(IV) and dichlorobis(cyclopentadienyl) hafnium(IV);

tantalum-containing compounds such as tetrabutoxy tantalum(IV), pentabutoxy tantalum(V) and pentaethoxy tantalum(V);

tungsten-containing compounds such as tetrabutoxy tungsten(IV), pentabutoxy tungsten(V), pentamethoxy tungsten(V), hexabutoxy tungsten(VI), hexaethoxy so tungsten(VI) and dichlorobis(cyclopentadienyl)tungsten(IV);

iron-containing compounds such as iron chloride(III);

ruthenium-containing compounds such as diacetato[(S)-(−)-2,2′-bis(diphenylphosphino)-1,1′-binaphthyl] ruthenium(II);

cobalt-containing compounds such as dichloro[ethylenebis(diphenylphosphine)] cobalt(II);

zinc-containing compounds such as diisopropoxy zinc(II) and zinc(II) acetate;

aluminum-containing compounds such as diisopropoxyethylacetoacetate aluminum(III) and aluminum(III) acetate;

indium-containing compounds such as indium(III) acetate and triisopropoxy indium(III);

tin-containing compounds such as tetraethyldiacetoxy stannoxane, tetrabutoxy tin(IV), tetraisopropoxy tin(IV) and t-butyltris(diethylamide) tin(IV); and

germanium-containing compounds such as tetraisopropoxy germanium(IV).

Upon the synthesis reaction of the compound (A), in addition to the metal compound (I), a compound that can be the monodentate ligand or the polydentate ligand, a compound that can be a bridging ligand, etc. may also be added. The compound that can be the bridging ligand is exemplified by a compound having a hydroxy group, an isocyanate group, an amino group, an ester group or an amide group each in a plurality of number, and the like.

A procedure for carrying out the hydrolytic condensation reaction using the metal-containing compound (b) may be exemplified by: a procedure of hydrolytically condensing the metal-containing compound (b) in a solvent containing water; and the like. In this case, an other compound having a hydrolyzable group may be added as needed. Also, an acid such as acetic acid may be added as a catalyst of the hydrolytic condensation reaction. The lower limit of the amount of water used for the hydrolytic so condensation reaction is preferably 0.2 times the molar amount, more preferably an equimolar amount, and still more preferably 3 times molar amount with respect to the hydrolyzable group included in the metal-containing compound (b) and the like. The upper limit of the amount of water is preferably 20 times molar amount, more preferably 15 times molar amount, and still more preferably 10 times molar amount.

The solvent for use in the synthesis reaction of the compound (A) is not particularly limited, and solvents similar to those exemplified in connection with the solvent (B) described later may be used. Of these, esters, alcohols and/or ethers are preferred, alcohols are more preferred, polyhydric alcohol partial ethers are still more preferred, and propylene glycol monomethyl ether is particularly preferred.

In the case in which a solvent is used in the synthesis reaction of the compound (A), the solvent used may be either removed after the completion of the reaction, or directly used as the solvent (B) in the film-forming composition without removal thereof.

The lower limit of the temperature of the synthesis reaction of the compound (A) is preferably 0° C., and more preferably 10° C. The upper limit of the aforementioned temperature is preferably 150° C., and more preferably 100° C.

The lower limit of the time period of the synthesis reaction of the compound (A) is preferably 1 min, more preferably 10 min, and still more preferably 1 hour. The upper limit of the time period is preferably 100 hrs, more preferably 50 hrs, and still more preferably 10 hrs.

### (B) Solvent

The solvent (B) dissolves or disperses the compound (A), and optional component(s) which may be contained as needed. The solvent (B) includes the solvent component (B1) and the solvent component (B2). Further, the solvent (B) includes an alcohol solvent, and a percentage content of the alcohol solvent in the solvent (B) is no less than 30% by mass. The solvent (B) may contain a solvent component other the solvent component (B1) and the solvent component (B2), within a range not leading to impairment of the effects of the present invention. Each aforementioned solvent component may be used alone or in a combination of two or more types thereof.

Due to the film-forming composition containing the solvent (B) in addition to the compound (A), wherein: this solvent (B) includes the solvent component (B1) and the solvent component (B2); the solvent (B) includes an alcohol solvent; and the percentage content of alcohol solvent in the solvent (B) is no less than 30% by mass, the variation-inhibiting property regarding coating film thickness and the variation-inhibiting property regarding resist sensitivity to an extreme ultraviolet ray or electron beam are each superior. Although not necessarily clarified and without wishing to be bound by any theory, the reason for achieving the effects described above owing to the film-forming composition having the aforementioned constitution may be supposed as in the following, for example. By using as the solvent (B), a mixture of the solvent component (B1) having a low boiling point and the solvent component (B2) having a high boiling point, it is believed that variation in film qualities of the formed metal-containing films resulting from a difference in a time period from immediately after applying the film-forming composition until starting heating of the coating film can be inhibited. It is considered that as a result, the variation-inhibiting property regarding coating film thickness of the metal-containing film formed from the film-forming composition and the variation-inhibiting property regarding resist sensitivity to an extreme ultraviolet ray or electron beam are improved.

The “alcohol solvent” as referred to herein means a solvent having at least one alcoholic hydroxyl group. The alcohol solvent is exemplified by alcohols, lactic acid esters and the like. The lower limit of the percentage content of the alcohol solvent in the solvent (B) is 30% by mass and is preferably 35% by mass, more preferably 40% by mass, and still more preferably 50% by mass. The upper limit of the percentage content is, for example, 100% by mass, preferably 95% by mass, more preferably 90% by mass, and still more preferably 70% by mass.

Each solvent component will be described in detail below.

(B1) Solvent Component

The solvent component (B1) is a solvent having a normal boiling point of less than 160° C.

The upper limit of the normal boiling point of the solvent component (B1) is preferably 158° C., and more preferably 156° C. When the normal boiling point of the solvent component (B1) is no greater than the upper limit described above, the coating characteristics of the film-forming composition can be further improved.

The lower limit of the normal boiling point of the solvent component (B1) is preferably 100° C., and more preferably 120° C. When the normal boiling point of the solvent component (B1) is no less than the lower limit described above, solubility of the optional component(s) can be further improved in the case in which the film-forming composition contains the optional component(s).

The lower limit of an SP value, which is a Hildebrand solubility parameter, of the solvent component (B1) is preferably 8 (cal/cm³)^{1/2}, more preferably 9 (cal/cm³)^{1/2}, and still more preferably 10 (cal/cm³)^{1/2} The upper limit of the SP value is preferably 17 (cal/cm³)^{1/2}, more preferably 16 (cal/cm³)^{1/2}, and still more preferably 15 (cal/cm³)^{1/2}. When the SP value falls within the above range, stability of the compound (A) in the film-forming composition can be further improved, and as a result, the variation-inhibiting property regarding coating film thickness and the variation-inhibiting property regarding resist sensitivity to an extreme ultraviolet ray or electron beam can be further improved.

With respect to the SP value, refer to values described in well-known documents such as Journal of Paint Technology Vol. 39, No. 505, February 1967 and the like.

The solvent component (B1) is exemplified by alcohols, esters, ethers, and the like.

Examples of the alcohols include:

monohydric alcohols such as methanol (boiling point: 65° C.), ethanol (boiling point: 78° C.), n-propanol (boiling point: 97° C.), iso-propanol (boiling point: 82° C.), n-butanol (boiling point: 117° C.), iso-butanol (boiling point: 108° C.), sec-butanol (boiling point: 99° C.), tert-butanol (boiling point: 82° C.), n-pentanol (boiling point: 138° C.), iso-pentanol (boiling point: 132° C.), 2-methylbutanol (boiling point: 136° C.), sec-pentanol (boiling point: 118° C.), tert-pentanol (boiling point: 102° C.), 2-methylpentanol (boiling point: 148° C.), 2-ethylbutanol (boiling point: 146° C.), 3-methoxybutanol (boiling point: 157° C.) and n-hexanol (boiling point: 157° C.); and

alkylene glycol monoalkyl ethers such as ethylene glycol monomethyl ether (boiling point: 125° C.), ethylene glycol monoethyl ether (boiling point: 135° C.), propylene glycol monomethyl ether (boiling point: 121° C.), propylene glycol monoethyl ether (boiling point: 133° C.) and propylene glycol monopropyl ether (boiling point: 149.8° C.).

Exemplary esters include carboxylic acid esters and the like.

Examples of the carboxylic acid esters include:

propionic acid esters such as iso-amyl propionate (boiling point: 156° C.) and the like; and

lactic acid esters such as ethyl lactate (boiling point: 151° C.).

Examples of the ethers include

alkylene glycol monoalkyl ether acetates such as ethylene glycol monomethyl ether acetate (boiling point: 145° C.) and propylene glycol monomethyl ether acetate (boiling point: 146° C.).

Of these, in light of abilities to further improve the solubility of the compound (A), the esters and/or the ethers are preferred; the carboxylic acid esters, the alkylene glycol monoalkyl ethers and/or the alkylene glycol monoalkyl ether acetates are more preferred; and the lactic acid esters, the alkylene glycol monoalkyl ethers and/or the alkylene glycol monoalkyl ether acetates are still more preferred as the solvent component (B1).

The lower limit of the percentage content of the solvent component (B1) in the solvent (B) is preferably 20% by mass, more preferably 35% by mass, and still more preferably 50% by mass. The upper limit of the percentage content is preferably 99% by mass, more preferably 97% by mass, and still more preferably 96% by mass. When the percentage content of the solvent (B1) falls within the above range, the variation-inhibiting property regarding coating film thickness and the variation-inhibiting property regarding resist sensitivity to an extreme ultraviolet ray or electron beam can be further improved.

(B2) Solvent Component

The solvent component (B2) is a solvent having a normal boiling point of no less than 160° C. and less than 400° C.

The lower limit of the normal boiling point of the solvent component (B2) is preferably 170° C., more preferably 180° C., and still more preferably 190° C. When the normal boiling point of the solvent component (B2) is no less than the lower limit described above, the variation-inhibiting property regarding coating film thickness and the variation-inhibiting property regarding resist sensitivity to an extreme ultraviolet ray or electron beam of the metal-containing film can be further improved.

The upper limit of the normal boiling point of the solvent component (B2) is preferably 350° C., more preferably 300° C., still more preferably 280° C., and particularly preferably 250° C. When the normal boiling point of the solvent component (B2) is no greater than the upper limit described above, the variation-inhibiting property regarding coating film thickness and the variation-inhibiting property regarding resist sensitivity to an extreme ultraviolet ray or electron beam can be further improved.

The solvent component (B2) is exemplified by esters, alcohols, ethers, carbonates, ketones, amides, and the like.

Examples of the esters include

carboxylic acid esters, e.g.:

acetic acid esters such as 2-ethylbutyl acetate (boiling point: 160° C.), 2-ethylhexyl acetate (boiling point: 199° C.), benzyl acetate (boiling point: 212° C.), cyclohexyl acetate (boiling point: 172° C.), methylcyclohexyl acetate (boiling point: 201° C.), n-nonyl acetate (boiling point: 208° C.) and 1,6-diacetoxyhexane (boiling point: 260° C.);

acetoacetic acid esters such as methyl acetoacetate (boiling point: 169° C.) and ethyl acetoacetate (boiling point: 181° C.);

propionic acid esters such as iso-amyl propionate (boiling point: 156° C.);

oxalic acid esters such as diethyl oxalate (boiling point: 185° C.) and di-n-butyl oxalate (boiling point: 239° C.);

lactic acid esters such as n-butyl lactate (boiling point: 185° C.);

malonic acid esters such as diethyl malonate (boiling point: 199° C.);

phthalic acid esters such as dimethyl phthalate (boiling point: 283° C.);

lactones such as β-propiolactone (boiling point: 162° C.), γ-butyrolactone (boiling point: 204° C.), γ-valerolactone (boiling point: 207° C.) and γ-undecalactone (boiling point: 286° C.); and the like.

Examples of the alcohols include:

monohydric alcohols such as n-octanol (boiling point: 194° C.), sec-octanol (boiling point: 174° C.), n-nonyl alcohol (boiling point: 215° C.), n-decanol (boiling point: 228° C.), phenol (boiling point: 182° C.), cyclohexanol (boiling point: 161° C.) and benzyl alcohol (boiling point: 205° C.);

polyhydric alcohols such as ethylene glycol (boiling point: 197° C.), 1,2-propylene glycol (boiling point: 188° C.), 1,3-butylene glycol (boiling point: 208° C.), 2,4-pentanediol (boiling point: 201° C.), 2-methyl-2,4-pentanediol (boiling point: 196° C.), 2,5-hexanediol (boiling point: 216° C.), triethylene glycol (boiling point: 165° C.) and dipropylene glycol (boiling point: 230° C.); and

polyhydric alcohol partial ethers such as ethylene glycol monobutyl ether (boiling point: 171° C.), ethylene glycol monophenyl ether (boiling point: 244° C.), diethylene glycol monomethyl ether (boiling point: 194° C.), diethylene glycol monoethyl ether (boiling point: 202° C.), triethylene glycol monomethyl ether (boiling point: 249° C.), diethylene glycol monoisopropyl ether (boiling point: 207° C.), diethylene glycol monobutyl ether (boiling point: 231° C.), triethylene glycol monobutyl ether (boiling point: 271° C.), ethylene glycol monoisobutyl ether (boiling point: 161° C.), diethylene glycol monoisobutyl ether (boiling point: 220° C.), ethylene glycol monohexyl ether (boiling point: 208° C.), diethylene glycol monohexyl ether (boiling point: 259° C.), ethylene glycol mono2-ethylhexyl ether (boiling point: 229° C.), diethylene glycol mono2-ethylhexyl ether (boiling point: 272° C.), ethylene glycol monoallyl ether (boiling point: 159° C.), diethylene glycol monophenyl ether (boiling point: 283° C.), ethylene glycol monobenzyl ether (boiling point: 256° C.), diethylene glycol monobenzyl ether (boiling point: 302° C.), dipropylene glycol monomethyl ether (boiling point: 187° C.), tripropylene glycol monomethyl ether (boiling point: 242° C.), dipropylene glycol monopropyl ether (boiling point: 212° C.), propylene glycol monobutyl ether (boiling point: 170° C.), dipropylene glycol monobutyl ether (boiling point: 231° C.) and propylene glycol monophenyl ether (boiling point: 243° C.).

Examples of the ethers include:

dialkylene glycol monoalkyl ether acetates such as dipropylene glycol monomethyl ether acetate (normal boiling point: 213° C.), diethylene glycol monoethyl ether acetate (boiling point: 217° C.) and diethylene glycol monobutyl ether acetate (normal boiling point: 247° C.);
alkylene glycol monoalkyl ether acetates such as butylene glycol monomethyl ether acetate (boiling point: 172° C.) and ethylene glycol monobutyl ether acetate (boiling point: 188° C.);

dialkylene glycol dialkyl ethers such as diethylene glycol dimethyl ether (boiling point: 162° C.), diethylene glycol methyl ethyl ether (boiling point: 176° C.), diethylene glycol diethyl ether (boiling point: 189° C.), diethylene glycol dibutyl ether (boiling point: 255° C.) and dipropylene glycol dimethyl ether (boiling point: 171° C.);

trialkylene glycol dialkyl ethers such as triethylene glycol dimethyl ether (boiling point: 216° C.);

tetraalkylene glycol dialkyl ethers such as tetraethylene glycol dimethyl ether (boiling point: 275° C.); and

other ethers such as 1,8-cineol (boiling point: 176° C.), diisopentyl ether (boiling point: 171° C.), ethyl benzyl ether (boiling point: 189° C.), diphenyl ether (boiling point: 259° C.), dibenzyl ether (boiling point: 297° C.) and hexyl ether (boiling point: 226° C.).

Examples of the carbonates include ethylene carbonate (boiling point: 244° C.), propylene carbonate (boiling point: 242° C.) and the like.

Examples of the ketones include ethyl amyl ketone (boiling point: 167° C.), dibutyl ketone (boiling point: 186° C.), diamyl ketone (boiling point: 228° C.), and the like.

Examples of the amides include N-methylpyrrolidone (boiling point: 204° C.), N,N-dimethylacetamide (boiling point: 165° C.), formamide (boiling point: 210° C.), N-ethylacetamide (boiling point: 206° C.), N-methylacetamide (boiling point: 206° C.), and the like.

Examples of the other solvent component (B2) include furfural (boiling point: 162° C.), dimethyl sulfoxide (boiling point: 189° C.), sulfolane (boiling point: 287° C.), glycerin (boiling point: 290° C.), succinonitrile (boiling point: 265° C.), nitrobenzene (boiling point: 211° C.), and the like.

Of these, as the solvent component (B2), the esters, the alcohols, the ethers and/or the carbonates are preferred. Furthermore, as the esters, the carboxylic acid esters are preferred. As the alcohols, the polyhydric alcohols and/or the polyhydric alcohol partial ethers are preferred. As the ethers, the dialkylene glycol monoalkyl ether acetates are preferred.

The lower limit of the relative evaporation rate of the solvent component (B2) is, provided that an evaporation rate of butyl acetate is 100, preferably 0.01, more preferably 0.05, and still more preferably 0.1. When the relative evaporation rate of the solvent component (B2) is no less than the lower limit described above, residues from the solvent after the forming of the metal-containing film can be reduced.

The upper limit of the relative evaporation rate of the solvent component (B2) is, provided that an evaporation rate of butyl acetate is 100, preferably 10, more preferably 8, still more preferably 6, and particularly preferably 4. When the relative evaporation rate of the solvent component (B2) is no greater than the upper limit described above, the variation-inhibiting property regarding coating film thickness and the variation-inhibiting property regarding resist sensitivity to an extreme ultraviolet ray or electron beam of the metal-containing film can be further improved.

It is to be noted that the “relative evaporation rate” as referred to herein means an evaporation rate value as measured in accordance with ASTM-D3539 under a condition at 25° C. and at 1 atm.

Examples of the solvent component (B2) having the relative evaporation rate falling within the above range include propylene glycol monopropyl ether (relative evaporation rate: 21), propylene glycol monobutyl ether (relative evaporation rate: 7), dipropylene glycol monomethyl ether acetate (relative evaporation rate: 1.5), diethylene so glycol monoethyl ether acetate (relative evaporation rate: 1), diethylene glycol monobutyl ether acetate (relative evaporation rate: <1), dipropylene glycol monomethyl ether (relative evaporation rate: 3), dipropylene glycol monobutyl ether (relative evaporation rate: 1), tripropylene glycol monomethyl ether (relative evaporation rate: <1), γ-butyrolactone (relative evaporation rate: <1), and the like.

The lower limit of the percentage content of the solvent component (B2) in the solvent (B) is preferably 0.1% by mass, more preferably 1% by mass, still more preferably 2% by mass, particularly preferably 4% by mass, and more particularly preferably 8% by mass. The upper limit of the percentage content is preferably 90% by mass, more preferably 65% by mass, still more preferably 50% by mass, particularly preferably 30% by mass, and more particularly preferably 20% by mass.

### Optional Components

The film-forming composition may contain as the optional component, for example, a basic compound (including a base generator), a radical generating agent, an acid generating agent, and/or a surfactant. The film-forming composition may contain one, or two or more types of each of the optional components. In a case in which the film-forming composition contains the optional component(s), the upper limit of the content of the optional component(s) with respect to 100 parts by mass of the compound (A) is, for example, 2 parts by mass.

### Preparation Procedure of Film-Forming Composition

The film-forming composition may be prepared by, for example, mixing at a predetermined ratio, the compound (A), the solvent (B) and as needed the optional component(s), and preferably filtering through a membrane filter having a pore size of no greater than approximately 0.2 μm a mixture thus obtained.

The lower limit of the solid content concentration of the film-forming composition is preferably 0.1% by mass, more preferably 0.5% by mass, still more preferably 1% by mass, and particularly preferably 1.5% by mass. The upper limit of the solid content concentration is preferably 50% by mass, more preferably 30% by mass, still more preferably 10% by mass, and particularly preferably 5% by mass.

The solid content concentration of the film-forming composition as referred to herein means a value (% by mass) as determined by: baking 0.5 g of the film-forming composition at 250° C. for 30 min; measuring the mass of the solid content in the film-forming composition; and dividing the mass of the solid content by the mass of the film-forming composition.

### Pattern-Forming Method

The pattern-forming method of the other embodiment of the present invention includes the steps of: applying the metal-containing film-forming composition of the one embodiment of the present invention directly or indirectly on at least an upper face side of a substrate to form a metal-containing film (hereinafter, may be also referred to as “metal-containing film-forming composition applying step”); applying a composition for resist film formation directly or indirectly on an upper face side of the metal-containing film to form a resist film (hereinafter, may be also referred to as “composition for resist film formation applying step”); exposing the resist film to an extreme ultraviolet ray or electron beam (hereinafter, may be also referred to as “exposing step”); and developing the resist film exposed (hereinafter, may be also referred to as “developing step”). Furthermore, a step of etching the metal-containing film using as a mask the resist film developed (hereinafter, may be also referred to as “etching step”) may be also included.

It is preferred that the pattern-forming method further includes a step of forming an organic underlayer film directly or indirectly on at least an upper face side of the substrate (hereinafter, may be also referred to as “organic underlayer film-forming step”) before the metal-containing film-forming composition applying step.

Moreover, the pattern-forming method may further include the step of etching the substrate (hereinafter, may be also referred to as “substrate-etching step”) using as a so mask the metal-containing film etched.

The pattern-forming method leads to formation of the metal-containing film with the variation-inhibiting property regarding coating film thickness and the variation-inhibiting property regarding resist sensitivity to an extreme ultraviolet ray or electron beam, each being superior, since the film-forming composition described above is used, thereby enabling further microfabrication of a pattern formed on the substrate through the use of the metal-containing film. Hereinafter, each step will be described in detail.

Organic Underlayer Film-Forming Step

In this step, an organic underlayer film is formed directly or indirectly on at least an upper face side of the substrate.

In a case in which the organic underlayer film-forming step is carried out in the pattern-forming method, the metal-containing film-forming composition applying step described later is carried out after the organic underlayer film-forming step. In this case, the metal-containing film is formed by applying the film-forming composition on the organic underlayer film in the metal-containing film-forming composition applying step.

The substrate is exemplified by insulating films of silicon oxide, silicon nitride, silicon nitride oxide, polysiloxane or the like, resin substrates, and the like. Examples of the substrate which may be used include interlayer insulating films such as wafers coated with a low-dielectric insulating film formed from “Black Diamond” available from AMAT, “SiLK” available from Dow Chemical, “LKD5109” available from JSR Corporation or the like. A substrate patterned to have wiring grooves (trenches), plug grooves (vias) or the like may also be used as the substrate.

The organic underlayer film is different from the metal-containing film formed from the film-forming composition described above. The organic underlayer film serves in further compensating for a function exhibited by the metal-containing film and/or the resist film in resist pattern formation, as well as in imparting a necessary certain function for attaining a function not exhibited by the silicon-containing film and/or the resist film (for example, an antireflective property, coating film flatness, and high etching resistance to fluorine-based gas).

The organic underlayer film is exemplified by an antireflective film and the like. An exemplary antireflective film-forming composition may include “NFC HM8006” available from JSR Corporation, and the like.

The organic underlayer film may be formed by, for example, applying an organic underlayer film-forming composition through spin coating or the like to form a coating film, and then heating.

Metal-Containing Film-Forming Composition Applying Step

In this step, the film-forming composition is applied. According to this step, the coating film of the film-forming composition is formed on the substrate directly or via another layer such as the organic underlayer film. A procedure for applying the film-forming composition is not particularly limited, and for example, a well-known procedure such as, e.g., spin-coating may be exemplified.

The metal-containing film is formed by, for example, subjecting the coating film formed by applying the film-forming composition on the substrate or the like to typically exposure and/or heating, thereby allowing for hardening.

Examples of the radioactive ray which may be used for the exposure include: electromagnetic waves such as a visible light ray, an ultraviolet ray, a far ultraviolet ray, an X-ray and a γ-ray; particle rays such as an electron beam, a molecular beam and an ion beam; and the like.

The lower limit of the temperature when heating the coating film is preferably 90° C., more preferably 150° C., and still more preferably 200° C. The upper limit of the temperature is preferably 550° C., more preferably 450° C., and still more preferably 300° C. The lower limit of the average thickness of the metal-containing film formed is preferably 1 nm, more preferably 5 nm, and still more preferably 10 nm. The upper limit of the average thickness is preferably 200 nm, more preferably 100 nm, and still more preferably 50 nm.

Composition for Resist Film Formation Applying Step

In this step, the composition for resist film formation is applied directly or indirectly on an upper face side of the metal-containing film formed by the metal-containing film-forming composition applying step. By this step, the resist film is formed on the upper face side of the metal-containing film on the substrate.

The composition for resist film formation is exemplified by a radiation-sensitive resin composition containing a polymer having an acid-labile group and a radiation-sensitive acid generating agent (chemically amplified resist composition), a positive resist composition containing an alkali-soluble resin and a quinone diazide-based photosensitizing agent, a negative resist composition containing an alkali-soluble resin and a crosslinking agent, and the like. Of these, the radiation-sensitive resin composition is preferred. In a case where the radiation-sensitive resin composition is used, formation of a positive pattern is enabled by developing with an alkaline developer solution, whereas formation of a negative pattern is enabled by developing with an organic solvent developer solution. For forming the resist pattern, a procedure for fine pattern formation such as double patterning, double exposure or the like may be appropriately employed.

The polymer contained in the radiation-sensitive resin composition may have, in addition to a structural unit that includes the acid-labile group, for example, a structural unit that includes a lactone structure, a cyclic carbonate structure and/or a sultone structure; a structural unit that includes an alcoholic hydroxyl group; a structural unit that includes a phenolic hydroxyl group; a structural unit that includes a fluorine atom; etc. When the polymer has the structural unit that includes a phenolic hydroxyl group and/or the structural unit that includes a fluorine atom, an improvement in sensitivity is enabled in the case of using an extreme ultraviolet ray as the radioactive ray in the exposure.

The lower limit of the solid content concentration of the composition for resist film formation is preferably 0.1% by mass, and more preferably 1% by mass. The upper limit of the solid content concentration is preferably 50% by mass, and more preferably 30% by mass. The composition for resist film formation filtered through a filter having a pore size of about no greater than 0.2 μm may be suitably used. In the pattern-forming method, a commercially available resist composition may be directly used as the composition for resist film formation.

A procedure for applying the composition for resist film formation may be exemplified by a conventional method such as, e.g., spin coating. In applying the composition for resist film formation, the amount of the composition for resist film formation to be applied is adjusted such that the resist film obtained has a predetermined film thickness.

The resist film may be formed by prebaking the coating film of the composition for resist film formation to allow the solvent in the coating film to be volatilized. The prebaking temperature may be appropriately adjusted depending on the type, etc., of the composition for resist film formation used. The lower limit of the prebaking temperature is preferably 30° C., and more preferably 50° C. The upper limit of the prebaking temperature is preferably 200° C., and more preferably 150° C.

Exposing Step

In this step, the resist film formed by the composition for resist film formation applying step is exposed to an extreme ultraviolet ray or electron beam. The exposure is carried out by, for example, selectively irradiating a certain region of the resist film.

Developing Step

In this step, the resist film exposed is developed. By this step, the resist pattern is formed on the upper face side of the metal-containing film on the substrate. The development procedure may be either development with an alkali carried out using an alkaline developer solution, or development with an organic solvent carried out using an organic solvent developer solution. In this step, development is carried out with various types of developer solution, preferably followed by washing and drying, whereby a predetermined resist pattern corresponding to the shape exposed in the exposing step is formed.

Etching Step

In this step, by using as a mask the resist pattern formed by the developing step, the metal-containing film is etched. More specifically, the metal-containing film is patterned by etching once or a plurality of times, with the resist pattern formed by the developing step used as a mask.

The etching may be either dry etching or wet etching, but dry etching is preferred.

The dry etching may be carried out by using, for example, a well-known dry etching apparatus. The etching gas for use in the dry etching may be appropriately selected depending on an element composition and the like of the metal-containing film to be etched, and examples of the etching gas which may be used include: fluorine-based gases such as CHF₃, CF₄, C₂F₆, C₃F₈ and SF₆; chlorine-based gases such as Cl₂ and BCl₃; oxygen-based gases such as O₂, O₃ and H₂O; reductive gases such as H₂, NH₃, CO, CH₄, C₂H₂, C₂H₄, C₂H₆, C₃H₄, C₃H₆, C₃H₈, HF, HI, HBr, HCl, NO, NH₃ and BCl₃; inert gases such as He, N₂ and Ar; and the like. These gases may be used as a mixture. In dry etching of the metal-containing film, the fluorine-based gas is typically used, and a mixture obtained by adding a chlorine-based gas and an inert gas to the fluorine-based gas may be suitably used.

Substrate-Etching Step

In this step, the substrate is etched by using as a mask the metal-containing film etched as described above. More specifically, a patterned substrate is obtained by conducting the etching once or a plurality of times, with the pattern formed on the metal-containing film obtained by the etching step described above used as a mask.

In a case in which the organic underlayer film is formed on the substrate, the pattern is formed on the substrate by: using the etched metal-containing film as the so mask in etching the organic underlayer film to form an organic underlayer film pattern; and using the organic underlayer film pattern as the mask in etching the substrate.

The etching may be either dry etching or wet etching, and the dry etching is preferred. The dry etching when forming the pattern on the organic underlayer film so may be carried out by using, for example, a well-known dry etching apparatus. An etching gas used for the dry etching may be appropriately selected depending on an element composition and the like of the metal-containing film and the organic underlayer film to be etched. Examples of the etching gas which may be used for the dry etching include etching gases similar to those exemplified as the etching gas for use in the dry etching of the metal-containing film and the like, and these gases may be used as a mixture. In the dry etching of the organic underlayer film with the metal-containing film pattern as a mask, the oxygen-based gas is typically used.

The dry etching in etching the substrate with the organic underlayer film pattern as the mask may be carried out by using, for example, a known dry etching apparatus. An etching gas used for the dry etching may be appropriately selected depending on an element composition and the like of the organic underlayer film and the substrate to be etched. For example, etching gases similar to those exemplified as the etching gases which may be used in the dry etching of the organic underlayer film may be exemplified. The etching may be carried out a plurality of times with different etching gases.

### EXAMPLES

Examples will be demonstrated herein below. It should be noted that the following Examples each merely illustrate one typical example of the present invention, and the scope of the present invention should not be construed to be narrowed by the Examples.

In the present Examples, the solid content concentration in the solution of the compound (A), the weight average molecular weight (Mw) of the compound (A), and the average thickness of the film were measured according to the following methods.

Solid Content Concentration of Solution of Compound (A)

The solid content concentration (% by mass) of the solution of the compound (A) was determined by baking 0.5 g of a solution of the compound (A) at 250° C. for 30 min, and measuring the mass of the solid content in 0.5 g of this solution.

Weight Average Molecular Weight (Mw)

Measurements were carried out by gel permeation chromatography (detector: differential refractometer) by using GPC columns (“AWM-H”×2, “AW-H”×1 and “AW2500”×1, available from Tosoh Corporation) under an analytical condition involving: a flow rate of 0.3 mL/min; an elution solvent of a mixture prepared by adding LiBr (30 mM) and citric acid (30 mM) to N,N′-dimethylacetamide; and a column temperature of 40° C., with mono-dispersed polystyrene as a standard.

Average Thickness of Film

The average thickness of the film was measured by using a spectroscopic ellipsometer (“M2000D” available from J.A. Woollam Co.).

### Preparation of Composition for Resist Film Formation

Compositions for resist film formation were prepared as in the following.

### Preparation Example 1

A composition for resist film formation (R-1) was obtained by mixing: 100 parts by mass of a polymer having a structural unit (1) derived from 4-hydroxystyrene, a structural unit (2) derived from styrene and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; and as solvents, 1,500 parts by mass of ethyl lactate and 700 parts by mass of propylene glycol monomethyl ether acetate, and filtering through a filter having a pore size of 0.2 μm the solution thus obtained.

### Preparation Example 2

A composition for resist film formation (R-2) was obtained by mixing: 100 parts by mass of a polymer having a structural unit (1) derived from 4-hydroxystyrene, a structural unit (2) derived from styrene and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; 1 part by mass of (A-1), being a metal compound described later; and as solvents, 1,500 parts by mass of ethyl lactate and 700 parts by mass of propylene glycol monomethyl ether acetate, and filtering through a filter having a pore size of 0.2 μm the solution thus obtained.

### Preparation Example 3

A composition for resist film formation (R-3) was obtained by mixing: 100 parts by mass of a polymer having a structural unit (1) derived from 4-hydroxystyrene, a structural unit (2) derived from styrene and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; 1 part by mass of (A-3), being a metal compound described later; and as solvents, 1,500 parts by mass of ethyl lactate and 700 parts by mass of propylene glycol monomethyl ether acetate, and filtering through a filter having a pore size of 0.2 μm the solution thus obtained.

### Synthesis of Compound (A)

Metal-containing compounds used for the syntheses of the compounds (A) are as presented below. It is to be noted that in the following Synthesis Examples, “parts by mass” means a value, provided that the total mass of the metal-containing compound so used was 100 parts by mass, unless otherwise specified particularly.

M-1: diisopropoxybis(2,4-pentanedionato) titanium (IV) (a solution in 2-propanol with a concentration of 75% by mass)

M-2: dibutoxybis(ethylacetoacetate) zirconium (IV) (a solution in n-butanol with a concentration of 70% by mass)

M-3: diisopropoxybis(2,4-pentanedionato) hafnium (IV)

M-4: tetraethoxy silane

M-5: diisopropoxyethylacetoacetate aluminum (III) (a solution in 2-propanol with a concentration of 75% by mass)

M-6: methyltrimethoxy silane

M-7: titanium (IV)butoxide oligomer decamer ([TiO(OBu)₂]₁₀)

### Synthesis Example 1: Synthesis of Compound (A-1)

In a reaction vessel, the compound (M-1) (100 parts by mass, excluding the solvent) was dissolved in 468 parts by mass of propylene glycol monoethyl ether. In the reaction vessel, 53 parts by mass of water were added dropwise over 10 min with stirring at room temperature (25° C. to 30° C.). Subsequently, the reaction was allowed at 60° C. for 2 hrs. After the completion of the reaction, the interior of the reaction vessel was cooled to no greater than 30° C. To the reaction solution thus cooled were added 654 parts by mass of propylene glycol monoethyl ether. Thereafter, water, alcohol generated by the reaction, and excess propylene glycol monoethyl ether were removed by using an evaporator to give a solution of the compound (A-1) in propylene glycol monoethyl ether. The Mw of the compound (A-1) was 4,200. The solid so content concentration of the propylene glycol monoethyl ether solution of the compound (A-1) was 7.6% by mass.

### Synthesis Example 2: Synthesis of Compound (A-2)

In a reaction vessel, the compound (M-2) (100 parts by mass, excluding the solvent) was dissolved in 1,325 parts by mass of propylene glycol monoethyl ether. In the reaction vessel, 7 parts by mass of water were added dropwise over 10 min with stirring at room temperature (25° C. to 30° C.). Subsequently, the reaction was allowed at 60° C. for 2 hrs. After the completion of the reaction, the interior of the reaction vessel was cooled to no greater than 30° C. To the reaction solution thus cooled were added 981 parts by mass of propylene glycol monoethyl ether. Thereafter, water, alcohol generated by the reaction, and excess propylene glycol monoethyl ether were removed by using an evaporator to give a solution of the compound (A-2) in propylene glycol monoethyl ether. The Mw of the compound (A-2) was 2,400. The solid content concentration of the propylene glycol monoethyl ether solution of the compound (A-2) was 13.0% by mass.

### Synthesis Example 3: Synthesis of Compound (A-3)

In a reaction vessel, the compound (M-3) and the compound (M-4) were dissolved in 168 parts by mass of propylene glycol monoethyl ether so as to give a molar ratio of 65/35 (mol %). In the reaction vessel, 9 parts by mass of an 18.9% by mass aqueous acetic acid solution were added dropwise over 10 min with stirring at room temperature (25° C. to 30° C.). Subsequently, the reaction was allowed at 95° C. for 5 hrs. After the completion of the reaction, the interior of the reaction vessel was cooled to no greater than 30° C. To the reaction solution thus cooled were added 400 parts by mass of propylene glycol monoethyl ether. Thereafter, water, alcohol generated by the reaction, and excess propylene glycol monoethyl ether were removed by using an evaporator to give a solution of the compound (A-3) in propylene glycol monoethyl ether. The Mw of the compound (A-3) was 2,300. The solid content concentration of the propylene glycol monoethyl ether solution of the compound (A-3) was 10.8% by mass.

### Synthesis Example 4: Synthesis of Compound (A-4)

In a reaction vessel, the compound (M-5) and the compound (M-6) were dissolved in 198 parts by mass of propylene glycol monoethyl ether so as to give a molar ratio of 10/90 (mol %). In the reaction vessel, 39 parts by mass of a 17.6% by mass aqueous acetic acid solution were added dropwise over 10 min with stirring at room temperature (25° C. to 30° C.). Subsequently, the reaction was allowed at 95° C. for 5 hrs. After the completion of the reaction, the interior of the reaction vessel was cooled to no greater than 30° C. To the reaction solution thus cooled were added 471 parts by mass of propylene glycol monoethyl ether. Thereafter, water, alcohol generated by the reaction, and excess propylene glycol monoethyl ether were removed by using an evaporator to give a solution of the compound (A-4) in propylene glycol monoethyl ether. The Mw of the compound (A-4) was 2,700. The solid content concentration of the propylene glycol monoethyl ether solution of the compound (A-4) was 13.1% by mass.

### Synthesis Example 5: Synthesis of Compound (A-5)

In a reaction vessel, the compound (M-7) (100 parts by mass, excluding the solvent) and 49.5 parts by mass of maleic anhydride were dissolved in 149.5 parts by mass of propylene glycol monoethyl ether. In the reaction vessel, replacement with nitrogen was carried out and then the reaction was allowed at 50° C. for 3 hrs. After the completion of the reaction, the interior of the reaction vessel was cooled to no greater than 30° C. to give a solution of the compound (A-5) in propylene glycol monoethyl ether. The Mw of the compound (A-5) was 3,200. The solid content concentration of the propylene glycol monoethyl ether solution of the compound (A-5) so was 27.2% by mass.

### Synthesis Example 6: Synthesis of Compound (A-6)

In a reaction vessel, the compound (M-1) (100 parts by mass, excluding the solvent) was dissolved in 468 parts by mass of propylene glycol monomethyl ether. In so the reaction vessel, 53 parts by mass of water were added dropwise over 10 min with stirring at room temperature (25° C. to 30° C.). Subsequently, the reaction was allowed at 60° C. for 2 hrs. After the completion of the reaction, the interior of the reaction vessel was cooled to no greater than 30° C. To the reaction solution thus cooled were added 654 parts by mass of propylene glycol monomethyl ether. Thereafter, water, alcohol generated by the reaction, and excess propylene glycol monomethyl ether were removed by using an evaporator to give a solution of the compound (A-6) in propylene glycol monomethyl ether. The Mw of the compound (A-6) was 4,200. The solid content concentration of the propylene glycol monomethyl ether solution of the compound (A-6) was 7.6% by mass.

### Preparation of Film-Forming Composition

Solvents (B) used for the preparation of the film-forming compositions are as presented below.
(B) Solvent
   (B1) Solvent component
B-1: propylene glycol monoethyl ether (normal boiling point: 132° C.)
B-2: propylene glycol monomethyl ether (normal boiling point: 121° C.)
B-3: ethyl lactate (normal boiling point: 151° C.)
B-4: propylene glycol monomethyl ether acetate (normal boiling point: 146° C.)
   (B2) Solvent component
B-5: dipropylene glycol monomethyl ether acetate (normal boiling point: 213° C.)
B-6: diethylene glycol monoethyl ether acetate (normal boiling point: 217° C.)
B-7: diethylene glycol monobutyl ether acetate (normal boiling point: 247° C.)
B-8: dipropylene glycol dimethyl ether (normal boiling point: 171° C.)
B-9: dipropylene glycol monomethyl ether (normal boiling point: 187° C.)
B-10: dipropylene glycol monobutyl ether (normal boiling point: 231° C.)
B-11: tripropylene glycol monomethyl ether (normal boiling point: 242° C.)
B-12: tripropylene glycol mono-n-butyl ether (normal boiling point: 275° C.)
B-13: γ-butyrolactone (normal boiling point: 204° C.)
B-14: benzyl alcohol (normal boiling point: 205° C.)
B-15: propylene carbonate (normal boiling point: 242° C.)
B-16: tetraethylene glycol dimethyl ether (normal boiling point: 275° C.)
B-17: 1,6-diacetoxyhexane (normal boiling point: 260° C.)
B-18: dipropylene glycol (normal boiling point: 231° C.)
B-19: triethylene glycol (normal boiling point: 287° C.)
B-20: glycerin (normal boiling point: 290° C.)
B-21: propylene glycol (normal boiling point: 188° C.)
B-22: tetraethylene glycol (normal boiling point: 327° C.)

### Example 1-1

A film-forming composition (J-1) was prepared by: mixing 2 parts by mass of (A-1) as the compound (A) (solid content), and as the solvents (B), 30 parts by mass of (B-1) (including also the solvent (B-1) contained in the solution of the compound (A)), 60 parts by mass of (B-4) and 10 parts by mass of (B-5); and filtering through a filter having a pore size of 0.2 μm the solution thus obtained.

### Examples 1-2 to 1-4 and 1-6 to 1-29, and Comparative Examples 1-1 and 1-2

Film-forming compositions (J-2) to (J-4) and (J-6) to (J-29), and (j-1) and (j-2) were prepared by a similar operation to Example 1 except that the type and the content of each component were as shown in Table 1 below. The denotation “-” in Table 1 below indicates that the corresponding component was not used.

### Example 1-5

A film-forming composition (J-5) was prepared by: mixing 2 parts by mass of (A-6) as the compound (A) (solid content), and as the solvents (B), 40 parts by mass of (B-2) (including also the solvent (B-2) contained in the solution of the compound (A)) and 60 parts by mass of (B-5); and filtering through a filter having a pore size of 0.2 μm the solution thus obtained.

TABLE 1

| | | (A) Compound | | | | | | | | | | |
|---|---|---|---|---|---|---|---|---|---|---|---|---|
| | Film- | | content | | | | | | | | | |
| | forming | | (parts by | (B) Solvent (type and parts by mass) | | | | | | | | |
| | composition | type | mass) | B-1 | B-2 | B-3 | B-4 | B-5 | B-6 | B-7 | B-8 | B-9 |
| Example 1-1 | J-1 | A-1 | 2 | 30 | — | — | 60 | 10 | — | — | — | — |
| Example 1-2 | J-2 | A-1 | 2 | 40 | — | — | 50 | 10 | — | — | — | — |
| Example 1-3 | J-3 | A-1 | 2 | 40 | — | 50 | — | 10 | — | — | — | — |
| Example 1-4 | J-4 | A-1 | 2 | 40 | — | — | — | 60 | — | — | — | — |
| Example 1-5 | J-5 | A-6 | 2 | — | 40 | — | — | 60 | — | — | — | — |
| Example 1-6 | J-6 | A-1 | 2 | 95 | — | — | — | 5 | — | — | — | — |
| Example 1-7 | J-7 | A-1 | 2 | 95 | — | — | — | — | 5 | — | — | — |
| Example 1-8 | J-8 | A-1 | 2 | 95 | — | — | — | — | — | 5 | — | — |
| Example 1-9 | J-9 | A-1 | 2 | 95 | — | — | — | — | — | — | 5 | — |
| Example 1-10 | J-10 | A-1 | 2 | 95 | — | — | — | — | — | — | — | 5 |
| Example 1-11 | J-11 | A-1 | 2 | 95 | — | — | — | — | — | — | — | — |
| Example 1-12 | J-12 | A-1 | 2 | 95 | — | — | — | — | — | — | — | — |
| Example 1-13 | J-13 | A-1 | 2 | 95 | — | — | — | — | — | — | — | — |
| Example 1-14 | J-14 | A-1 | 2 | 85 | — | — | — | — | — | — | — | — |
| Example 1-15 | J-15 | A-1 | 2 | 95 | — | — | — | — | — | — | — | — |
| Example 1-16 | J-16 | A-1 | 2 | 98 | — | — | — | — | — | — | — | — |
| Example 1-17 | J-17 | A-2 | 2 | 95 | — | — | — | — | — | — | — | — |
| Example 1-18 | J-18 | A-3 | 2 | 95 | — | — | — | — | — | — | — | — |
| Example 1-19 | J-19 | A-4 | 2 | 95 | — | — | — | — | — | — | — | — |
| Example 1-20 | J-20 | A-5 | 2 | 95 | — | — | — | — | — | — | — | — |
| Example 1-21 | J-21 | A-1 | 2 | 95 | — | — | — | — | — | — | — | — |
| Example 1-22 | J-22 | A-1 | 2 | 95 | — | — | — | — | — | — | — | — |
| Example 1-23 | J-23 | A-1 | 2 | 95 | — | — | — | — | — | — | — | — |
| Example 1-24 | J-24 | A-1 | 2 | 95 | — | — | — | — | — | — | — | — |
| Example 1-25 | J-25 | A-1 | 2 | 95 | — | — | — | — | — | — | — | — |
| Example 1-26 | J-26 | A-1 | 2 | 95 | — | — | — | — | — | — | — | — |
| Example 1-27 | J-27 | A-1 | 2 | 95 | — | — | — | — | — | — | — | — |
| Example 1-28 | J-28 | A-1 | 2 | 95 | — | — | — | — | — | — | — | — |
| Example 1-29 | J-29 | A-1 | 2 | 95 | — | — | — | — | — | — | — | — |
| Comparative | j-1 | A-1 | 2 | 100 | — | — | — | — | — | — | — | — |
| Example 1-1 | | | | | | | | | | | | |
| Comparative | j-2 | A-1 | 2 | 25 | — | — | 60 | — | — | — | — | — |
| Example 1-2 | | | | | | | | | | | | |

| | (B) Solvent (type and parts by mass) | | | | | | | | | | | | |
|---|---|---|---|---|---|---|---|---|---|---|---|---|---|
| | B-10 | B-11 | B-12 | B-13 | B-14 | B-15 | B-16 | B-17 | B-18 | B-19 | B-20 | B-21 | B-22 |
| Example 1-1 | — | — | — | — | — | — | — | — | — | — | — | — | — |
| Example 1-2 | — | — | — | — | — | — | — | — | — | — | — | — | — |
| Example 1-3 | — | — | — | — | — | — | — | — | — | — | — | — | — |
| Example 1-4 | — | — | — | — | — | — | — | — | — | — | — | — | — |
| Example 1-5 | — | — | — | — | — | — | — | — | — | — | — | — | — |
| Example 1-6 | — | — | — | — | — | — | — | — | — | — | — | — | — |
| Example 1-7 | — | — | — | — | — | — | — | — | — | — | — | — | — |
| Example 1-8 | — | — | — | — | — | — | — | — | — | — | — | — | — |
| Example 1-9 | — | — | — | — | — | — | — | — | — | — | — | — | — |
| Example 1-10 | — | — | — | — | — | — | — | — | — | — | — | — | — |
| Example 1-11 | 5 | — | — | — | — | — | — | — | — | — | — | — | — |
| Example 1-12 | — | 5 | — | — | — | — | — | — | — | — | — | — | — |
| Example 1-13 | — | — | 5 | — | — | — | — | — | — | — | — | — | — |
| Example 1-14 | — | — | — | 15 | — | — | — | — | — | — | — | — | — |
| Example 1-15 | — | — | — | 5 | — | — | — | — | — | — | — | — | — |
| Example 1-16 | — | — | — | 2 | — | — | — | — | — | — | — | — | — |
| Example 1-17 | — | — | — | 5 | — | — | — | — | — | — | — | — | — |
| Example 1-18 | — | — | — | 5 | — | — | — | — | — | — | — | — | — |
| Example 1-19 | — | — | — | 5 | — | — | — | — | — | — | — | — | — |
| Example 1-20 | — | — | — | 5 | — | — | — | — | — | — | — | — | — |
| Example 1-21 | — | — | — | — | 5 | — | — | — | — | — | — | — | — |
| Example 1-22 | — | — | — | — | — | 5 | — | — | — | — | — | — | — |
| Example 1-23 | — | — | — | — | — | — | 5 | — | — | — | — | — | — |
| Example 1-24 | — | — | — | — | — | — | — | 5 | — | — | — | — | — |
| Example 1-25 | — | — | — | — | — | — | — | — | 5 | — | — | — | — |
| Example 1-26 | — | — | — | — | — | — | — | — | — | 5 | — | — | — |
| Example 1-27 | — | — | — | — | — | — | — | — | — | — | 5 | — | — |
| Example 1-28 | — | — | — | — | — | — | — | — | — | — | — | 5 | — |
| Example 1-29 | — | — | — | — | — | — | — | — | — | — | — | — | 5 |
| Comparative | — | — | — | — | — | — | — | — | — | — | — | — | — |
| Example 1-1 | | | | | | | | | | | | | |
| Comparative | — | — | — | 15 | — | — | — | — | — | — | — | — | — |
| Example 1-2 | | | | | | | | | | | | | |

### Evaluations

The film-forming compositions prepared as described above were evaluated with regard to items described below, according to the following methods. The results of the evaluations are shown together in Tables 2 and 3 below. In Table 2, “-” denotes that the corresponding evaluation was not made.

Coating Characteristics

The film-forming composition prepared as described above was applied onto a silicon wafer (substrate) by spin coating with a spin coater (“CLEAN TRACK ACT8” available from Tokyo Electron Limited) under a condition at 1,500 rpm for 30 sec. Thereafter, a coating film thus obtained was heated at 250° C. for 60 sec to form a metal-containing film.

The metal-containing film thus formed was observed with an optical microscope, and evaluated to be: “A” (favorable) in a case of finding no coating unevenness; and “B” (unfavorable)” in a case of finding coating unevenness.

Variation-Inhibiting Property Regarding Coating Film Thickness

The film-forming composition prepared as described above was applied onto an 8-inch silicon wafer by spin coating with a spin coater (“CLEAN TRACK ACT8” available from Tokyo Electron Limited) under a condition at 1,500 rpm for 30 sec. Then, after a lapse of a predetermined time period, a metal-containing film was formed through heating at 250° C. for 60 sec, followed by cooling at 23° C. for 30 sec.

As the metal-containing films, “metal-containing film (a0)” in a case of the predetermined time period being 30 sec, and “metal-containing film (a1)” in a case of the predetermined time period being 120 sec were each formed. Provided that the average thickness of the metal-containing film (a0) was T₀, and the average thickness of the metal-containing film (a1) was T₁, a rate of change in the film thickness (%) was determined according to the following equation, and employed as a marker of the variation-inhibiting property regarding coating film thickness.

Rate of change in the film thickness (%)=|T₁−T₀|×100/T₀

The variation-inhibiting property regarding coating film thickness was evaluated to be: “A” (favorable) in a case of the rate of change in the film thickness being less than 1.7%; and “B” (unfavorable) in a case of the rate of change in the film thickness being no less than 1.7%.

Variation-Inhibiting Property Regarding Resist Sensitivity:

Sensitivity variation-inhibiting property of composition for resist film formation by exposure to electron beam

An antireflective film-forming material (“HM8006” available from JSR Corporation) was applied on an 8-inch silicon wafer by spin coating with the spin coater and thereafter heated at 250° C. for 60 sec to form an antireflective film having an so average thickness of 100 nm. The film-forming composition prepared as described above was applied onto the antireflective film by spin coating with the spin coater. Then, after a lapse of a predetermined time period, a metal-containing film having an average thickness of 30 nm was formed through heating at a heating temperature (° C.) for a heating time period (sec) shown in Table 3 below, followed by cooling at 23° C. for 30 sec. As the metal-containing film, “metal-containing film (b0)” in a case of the predetermined time period being 30 sec, and “metal-containing film (b1)” in a case of the predetermined time period being 120 sec were each formed. On the metal-containing film formed as described above, a composition for resist film formation shown in Table 3 was applied, heated at 130° C. for 60 sec, and then cooled at 23° C. for 30 sec to form a resist film having an average thickness of 50 nm.

The resist film was irradiated with an electron beam by using an electron beam writer (“HL800D” available from Hitachi, Ltd., output: 50 KeV; electric current density: 5.0 ampere/cm²). After the irradiation with the electron beam, the substrate was heated at 110° C. for 60 sec, and then cooled at 23° C. for 60 sec. Thereafter, a development was carried out using a 2.38% by mass aqueous TMAH solution (20 to 25° C.) with a puddle method, followed by washing with water and drying to give a substrate for evaluation on which a resist pattern was formed.

For line-width measurement of the resist pattern on the substrate for evaluation, a scanning electron microscope (“S9380” available from Hitachi High-Technologies Corporation) was used. On the substrate for evaluation, an exposure dose at which a 1:1 line-and-space with a line width of 100 nm was formed was defined as an optimum exposure dose, and a rate of change in the optimum exposure dose (%) was determined according to the following equation and employed as a marker of the variation-inhibiting property regarding resist sensitivity, provided that the optimum exposure dose on the substrate for evaluation 1 having the metal-containing film (b0) so was D₀ and that the optimum exposure dose on the substrate for evaluation 2 having the metal-containing film (b1) was D₁.

Rate of change in the optimum exposure dose (%)=|D₁−D₀|×100/D₀

The variation-inhibiting property regarding resist sensitivity was evaluated to be: “A” (favorable) in a case of the rate of change in the optimum exposure dose being less than 1%; and “B” (unfavorable) in a case of the rate of change in the optimum exposure dose being no less than 1%.

Sensitivity variation-inhibiting property of composition for resist film formation by exposure to extreme ultraviolet ray

An antireflective film-forming material (“HM8006” available from JSR Corporation) was applied on a 12-inch silicon wafer by spin coating with a spin coater (“CLEAN TRACK ACT12” available from Tokyo Electron Limited) and thereafter heated at 250° C. for 60 sec to form an antireflective film having an average thickness of 100 nm. The film-forming composition prepared as described above was applied onto the antireflective film by spin coating with the spin coater. Then, after a lapse of a predetermined time period, a metal-containing film having an average thickness of 30 nm was formed through heating at a heating temperature (° C.) for a heating time period (sec) shown in Table 3 below, followed by cooling at 23° C. for 30 sec. As the metal-containing film, “metal-containing film (b0)” in a case of the predetermined time period being 30 sec, and “metal-containing film (b1)” in a case of the predetermined time period being 120 sec were each formed. On the metal-containing film formed as described above, a composition for resist film formation shown in Table 3 was applied, heated at 130° C. for 60 sec, and then cooled at 23° C. for 30 sec to form a resist film having an average thickness of 50 nm.

The resist film was exposed by using an EUV scanner (“TWINSCAN NXE: 3300B” available from ASML Co., (NA=0.3; Sigma=0.9; quadrupole illumination, so with a 1:1 line-and-space mask having a line width of 25 nm in terms of a dimension on wafer)). After the exposure, the substrate was heated at 110° C. for 60 sec, and then cooled at 23° C. for 60 sec. Thereafter, a development was carried out using a 2.38% by mass aqueous TMAH solution (20 to 25° C.) with a puddle method, followed by washing with water and drying to give a substrate for evaluation on which a resist pattern was formed.

For line-width measurement and observation of the resist pattern on the substrate for evaluation, a scanning electron microscope (“CG-4000” available from Hitachi High-Technologies Corporation) was used. On the substrate for evaluation, an exposure dose at which a 1:1 line-and-space with a line width of 25 nm was formed was defined as an optimum exposure dose, and a rate of change in the optimum exposure dose (%) was determined according to the following equation and employed as a marker of the variation-inhibiting property regarding resist sensitivity, provided that the optimum exposure dose on the substrate for evaluation 1 having the metal-containing film (b0) was D₀ and that the optimum exposure dose on the substrate for evaluation 2 having the metal-containing film (b1) was D₁.

Rate of change in the optimum exposure dose (%)=|D₁−D₀|×100/D₀

The variation-inhibiting property regarding resist sensitivity was evaluated to be: “A” (favorable) in a case of the rate of change in the optimum exposure dose being less than 1%; and “B” (unfavorable) in a case of the rate of change in the optimum exposure dose being no less than 1%.

TABLE 2

| | | | Variation-inhibiting |
|---|---|---|---|
| | Film-forming | Coating | property regarding |
| | composition | characteristics | coating film thickness |
| Example 2-1 | J-1 | A | A |
| Example 2-2 | J-2 | A | A |
| Example 2-3 | J-3 | A | A |
| Example 2-4 | J-4 | A | A |
| Example 2-5 | J-5 | A | A |
| Example 2-6 | J-6 | A | A |
| Example 2-7 | J-7 | A | A |
| Example 2-8 | J-8 | A | A |
| Example 2-9 | J-9 | A | A |
| Example 2-10 | J-10 | A | A |
| Example 2-11 | J-11 | A | A |
| Example 2-12 | J-12 | A | A |
| Example 2-13 | J-13 | A | A |
| Example 2-14 | J-14 | A | A |
| Example 2-15 | J-15 | A | A |
| Example 2-16 | J-16 | A | A |
| Example 2-17 | J-17 | A | A |
| Example 2-18 | J-18 | A | A |
| Example 2-19 | J-19 | A | A |
| Example 2-20 | J-20 | A | A |
| Example 2-21 | J-21 | A | A |
| Example 2-22 | J-22 | A | A |
| Example 2-23 | J-23 | A | A |
| Example 2-24 | J-24 | A | A |
| Example 2-25 | J-25 | A | A |
| Example 2-26 | J-26 | A | A |
| Example 2-27 | J-27 | A | A |
| Example 2-28 | J-28 | A | A |
| Example 2-29 | J-29 | A | A |
| Comparative | j-1 | A | B |
| Example 2-1 | | | |
| Comparative | j-2 | B | — |
| Example 2-2 | | | |

TABLE 3

| | | | | | Variation-inhibiting property | |
|---|---|---|---|---|---|---|
| | Composition | | Heating | | regarding resist sensitivity | |
| | for resist film | Film-forming | heating temperature | heating time | Exposure to | Exposure to |
| | formation | composition | (° C.) | (sec) | electron beam | extreme ultraviolet ray |
| Example 3-1 | R-1 | J-1 | 250 | 60 | A | A |
| Example 3-2 | R-1 | J-2 | 250 | 60 | A | A |
| Example 3-3 | R-1 | J-3 | 250 | 60 | A | A |
| Example 3-4 | R-1 | J-4 | 250 | 60 | A | A |
| Example 3-5 | R-1 | J-5 | 250 | 60 | A | A |
| Example 3-6 | R-1 | J-6 | 250 | 60 | A | A |
| Example 3-7 | R-1 | J-7 | 250 | 60 | A | A |
| Example 3-8 | R-1 | J-8 | 250 | 60 | A | A |
| Example 3-9 | R-1 | J-9 | 250 | 60 | A | A |
| Example 3-10 | R-1 | J-10 | 250 | 60 | A | A |
| Example 3-11 | R-1 | J-11 | 250 | 60 | A | A |
| Example 3-12 | R-1 | J-12 | 250 | 60 | A | A |
| Example 3-13 | R-1 | J-13 | 250 | 60 | A | A |
| Example 3-14 | R-1 | J-14 | 250 | 60 | A | A |
| Example 3-15 | R-1 | J-15 | 250 | 60 | A | A |
| Example 3-16 | R-1 | J-16 | 250 | 60 | A | A |
| Example 3-17 | R-1 | J-17 | 250 | 60 | A | A |
| Example 3-18 | R-1 | J-18 | 250 | 60 | A | A |
| Example 3-19 | R-1 | J-19 | 250 | 60 | A | A |
| Example 3-20 | R-1 | J-20 | 250 | 60 | A | A |
| Example 3-21 | R-1 | J-21 | 250 | 60 | A | A |
| Example 3-22 | R-1 | J-22 | 250 | 60 | A | A |
| Example 3-23 | R-1 | J-23 | 250 | 60 | A | A |
| Example 3-24 | R-1 | J-24 | 250 | 60 | A | A |
| Example 3-25 | R-1 | J-25 | 250 | 60 | A | A |
| Example 3-26 | R-1 | J-26 | 250 | 60 | A | A |
| Example 3-27 | R-1 | J-27 | 250 | 60 | A | A |
| Example 3-28 | R-1 | J-28 | 250 | 60 | A | A |
| Example 3-29 | R-1 | J-29 | 250 | 60 | A | A |
| Example 3-30 | R-1 | J-1 | 300 | 60 | A | A |
| Example 3-31 | R-1 | J-1 | 350 | 60 | A | A |
| Example 3-32 | R-2 | J-1 | 300 | 60 | A | A |
| Example 3-33 | R-3 | J-1 | 300 | 60 | A | A |
| Comparative | R-1 | j-1 | 300 | 60 | B | B |
| Example 3-1 | | | | | | |

As is clear from the results shown in Tables 2 and 3, the metal-containing films formed from the film-forming compositions of the Examples were favorable in both the variation-inhibiting property regarding coating film thickness and the variation-inhibiting property regarding resist sensitivity. In contrast, the metal-containing films formed from the film-forming compositions of the Comparative Examples were unfavorable in the variation-inhibiting property regarding coating film thickness and the variation-inhibiting property regarding resist sensitivity.

According to the metal-containing film-forming composition for lithography with an extreme ultraviolet ray or electron beam, the metal-containing film for lithography with an extreme ultraviolet ray or electron beam, and the pattern-forming method of the embodiments of the present invention, a metal-containing film with a variation-inhibiting property regarding coating film thickness and a variation-inhibiting property regarding resist sensitivity, each being superior, is formed, and by using this metal-containing film, resist pattern size produced by an EUV lithography process becomes less likely to vary, thereby enabling a process yield of a semiconductor element to increase. Therefore, these can be suitably used for the manufacture, etc. of semiconductor devices, for which further progress of microfabrication is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A metal-containing film-forming composition for lithography with an extreme ultraviolet ray or electron beam, comprising:
a compound comprising a metal element and an oxygen atom, and further comprising a metal-oxygen covalent bond; and
a solvent, wherein
the metal element in the compound belongs to period 3 to period 7 of group 3 to group 15 in periodic table,
the solvent comprises a first solvent component having a normal boiling point of less than 160° C. and a second solvent component having a normal boiling point of no less than 160° C. and less than 400° C.,
the solvent comprises an alcohol solvent, and
a percentage content of the alcohol solvent in the solvent is no less than 30% by mass.

2. The metal-containing film-forming composition according to claim 1, wherein the first solvent component is an alkylene glycol monoalkyl ether, an alkylene glycol monoalkyl ether acetate, a lactic acid ester, or a combination thereof.

3. The metal-containing film-forming composition according to claim 1, wherein a percentage content of the second solvent component in the solvent is no less than 0.1% by mass and no greater than 90% by mass.

4. The metal-containing film-forming composition according to claim 1, wherein the second solvent component is an ester, an alcohol, an ether, a carbonate, or a combination thereof.

5. The metal-containing film-forming composition according to claim 4, wherein the ester is a carboxylic acid ester.

6. The metal-containing film-forming composition according to claim 4, wherein the alcohol is a polyhydric alcohol, a polyhydric alcohol partial ether, or a combination thereof.

7. The metal-containing film-forming composition according to claim 4, wherein the ether is a dialkylene glycol monoalkyl ether acetate.

8. The metal-containing film-forming composition according to claim 1, wherein a relative evaporation rate of the second solvent component is no less than 0.01 and no greater than 10, provided that a relative evaporation rate of butyl acetate is 100.

9. The metal-containing film-forming composition according to claim 1, wherein the compound is derived from a metal-containing compound comprising a hydrolyzable group represented by formula (1):
LₐMY_{b} (1)
wherein, in the formula (1), M represents a metal atom; L represents a ligand; a is an integer of 0 to 6, wherein in a case in which a is no less than 2, a plurality of Ls are identical or different; Y represents a hydrolyzable group selected from a halogen atom, an alkoxy group, a carboxylate group, an acyloxy group and —NRR′, wherein R and R′ each independently represent a hydrogen atom or a monovalent organic group having 1 to 20 carbon atoms; and b is an integer of 2 to 6, wherein a plurality of Ys are identical or different, and L represents a ligand not falling under a category of Y.

10. A metal-containing film for lithography with an extreme ultraviolet ray or electron beam formed from the metal-containing film-forming composition according to claim 1.

11. A pattern-forming method comprising:
applying the metal-containing film-forming composition according to claim 1 directly or indirectly on at least an upper face side of a substrate to form a metal-containing film;
applying a composition for resist film formation directly or indirectly on an upper face side of the metal-containing film to form a resist film;
exposing the resist film to an extreme ultraviolet ray or electron beam; and
developing the resist film exposed.

12. The pattern-forming method according to claim 11, further comprising
forming an organic underlayer film directly or indirectly on at least an upper face side of the substrate before applying the metal-containing film-forming so composition.
